(19) United States
(12) Patent Application Publication
(10) Pub. No.: US 2008/0189975 A1
(43) Pub. Date: Aug. 14, 2008

(54) SUBSTRATE PROCESSING APPARATUS AND SUBSTRATE PROCESSING METHOD

(76) Inventor: Katsuhiko MIYA, Kyoto (JP)

Correspondence Address: OSTROLENK FABER GERB & SOFFEN, 1180 AVENUE OF THE AMERICAS, NEW YORK, NY, 100368403, US

(21) Appl. No.: 12/021,391

(22) Filed: Jan. 29, 2008

(30) Foreign Application Priority Data
Feb. 14, 2007 (JP) JP2007-033398

(51) Int. Cl. F26B 5/08; F26B 25/08; H01L 21/687; B65G 47/24

(52) U.S. Cl. 34/317; 34/337; 34/58; 34/202; 414/781

(57) ABSTRACT

When chuck pins are in a releasing state, support pins for supporting a lower surface of a substrate at respective heights different from each other support the substrate in an inclined position. When the chuck pins are in a gripping state, substrate gripping parts grip a substrate sidewise to separate the substrate upwardly from a substrate rest part, thereby holding the substrate in a horizontal position at a predetermined gripping height. After a liquid mass covering the substrate is formed, the chuck pins are changed from the gripping state to the releasing state to support the substrate having been gripped in the horizontal position into an inclined position, thereby draining the liquid mass from the surface of the substrate. The substrate with the liquid mass drained from the surface thereof is held and rotated in a horizontal position. Thus, the substrate is dried. This allows the use of a simple structure to prevent the occurrence of water marks, thereby achieving good drying of the surface of the substrate.

### BACKGROUND OF THE INVENTION

1. Field of the Invention

The present invention relates to a substrate processing apparatus which performs a predetermined process on a substrate such as a semiconductor substrate, a glass substrate for a liquid crystal display device, a glass substrate for a photomask, a glass substrate for a plasma display, a substrate for an optical disk and the like (for example, which performs the process of removing a processing liquid from a surface of the substrate to dry the substrate).

2. Description of the Background Art

Conventionally, a substrate processing apparatus has been known which holds a substrate in a horizontal position and supplies a processing liquid (an etchant, a rinsing liquid and the like) to a surface of the substrate held in the horizontal position to perform a predetermined process on the substrate.

Such a substrate processing apparatus is disclosed, for example, in Japanese Patent Application Laid-Open No. 2004-235234. In this substrate processing apparatus, an unprocessed substrate transported into the apparatus by a transport robot is first supported on a horizontal support surface by a plurality of support members. Subsequently, the unprocessed substrate supported by the support members is horizontally held at a position higher than that of the support surface by a gripping member. Next, the substrate held by the gripping member is rotated, and a predetermined processing liquid is supplied to the rotating substrate. Thus, the substrate processing apparatus processes the substrate.

In such a substrate processing apparatus, the process of removing the processing liquid from the surface of the substrate to dry the substrate is carried out by rotating the substrate supplied with the processing liquid at a high speed to spin off the processing liquid from the substrate by centrifugal force (which is known as a spin-drying process).

There has been known a technique of temporarily placing the substrate with the processing liquid supplied to the surface thereof into an inclined position to drain the processing liquid from the substrate by using gravity before the substrate is rotated at a high speed in the spin-drying process. An example of this technique as disclosed in Japanese Patent Application Laid-Open No. 2006-19523 is such that, prior to the execution of the spin-drying process, a substrate inclining mechanism raises a single portion of the periphery of a substrate with a rinsing liquid supplied to the surface thereof to incline the substrate, thereby dropping down the rinsing liquid from the surface of the substrate. Such a structure which inclines the substrate to drain the liquid from the upper surface of the substrate by using gravity can efficiently drain the liquid from the substrate to eliminate droplets remaining on the substrate. This prevents the occurrence of water marks to achieve good drying of the surface of the substrate.

An example of the technique of placing a substrate in an inclined position is disclosed in Japanese Patent Application Laid-Open No. 2003-282670 in which a substrate is transported while being held in an inclined position. According to this technique, a restriction member and an inclination member which are provided on a hand for holding and transporting a substrate thereon are used to transport the substrate while supporting the substrate in an inclined position. More specifically, one edge portion of the substrate is supported in an inclined position by an inclined surface of the inclination member, and the opposite edge portion of the substrate is guided in abutment with the restriction member. The abutment of the edge portion of the substrate with the restriction member allows the accurate positioning and holding of the substrate.

As mentioned above, draining the processing liquid from the substrate before the high-speed rotation of the substrate prevents the occurrence of water marks to achieve good drying of the surface of the substrate.

However, the structure disclosed in Japanese Patent Application Laid-Open No. 2006-19523 is required to provide the substrate inclining mechanism for inclining the substrate. Enormous design efforts are required to provide such a special mechanism only for the purpose of inclining the substrate, and the increase in costs of the apparatus and the increase in footprint are unavoidable.

Additionally, this structure necessitates a series of steps for inclining the substrate (i.e., the steps of moving an arm of the substrate inclining mechanism to the periphery of the substrate, gripping and raising a single portion of the periphery of the substrate at that position, and changing the substrate from the inclined position again to a horizontal position). In view of the time required for the arm to move and the like, this structure presents another problem in that the decrease in throughput is unavoidable.

Further, this structure presents still another unavoidable problem in accumulated contamination because of the difficulties in cleaning the arm of the substrate inclining mechanism. The contamination of the arm results in the contamination of the back surface of the substrate with which the arm is brought into contact. Deposition of dust and the like on the back surface of the substrate causes a transfer problem in a subsequent batch process. To avoid these problems, it is desirable to provide a mechanism for cleaning the arm of the substrate inclining mechanism. The provision of such a cleaning mechanism, however, gives rise to the further increase in costs of the apparatus and the further increase in footprint.

### SUMMARY OF THE INVENTION

The present invention is intended for a substrate processing apparatus for removing a processing liquid from a surface of a substrate to dry the substrate.

According to the present invention, the substrate processing apparatus comprises: a rotatable support table for rotatably supporting a substrate; a substrate rest part provided on the rotatable support table and for placing a substrate in an inclined position thereon; a gripping part provided on the rotatable support table and for gripping an edge portion of a substrate to hold the substrate in a horizontal position; a drive mechanism for moving the gripping part so that the gripping part is changed between a horizontal holding state in which the gripping part grips the edge portion of the substrate to hold the substrate in the horizontal position and an inclined holding state in which the gripping part is spaced apart from the edge portion of the substrate and the substrate rest part holds the substrate in the inclined position; and a rotating element for rotating the rotatable support table about a vertical axis in the horizontal holding state.

The placement of the substrate allows the processing liquid to be removed from the surface of the substrate by gravity. Holding and rotating the substrate with the processing liquid removed from the surface thereof in the horizontal position prevent the occurrence of water marks to achieve good drying of the surface of the substrate.

The substrate is placed in the inclined position by moving the gripping part. Thus, there is no need to provide a mechanism for raising an edge portion of the substrate and the like to place the substrate in the inclined position. This enables the substrate processing apparatus to have a simple structure.

Preferably, the substrate rest part includes a plurality of support pins differing in height from each other. The gripping part includes a plurality of grippers provided in a one-to-one correspondence with the plurality of support pins. The plurality of support pins and the plurality of grippers corresponding thereto are provided on a plurality of rotatable bases, respectively, which are mounted on the rotatable support table rotatably on a vertical axis. Each of the plurality of grippers has tapered surfaces of a V-shaped cross-sectional configuration which receive the edge portion of the substrate. The plurality of grippers are provided on the plurality of rotatable bases at eccentric positions relative to the rotation centers of the plurality of rotatable bases, respectively. By rotating the plurality of rotatable bases, the drive mechanism brings the plurality of grippers in spaced apart relation to the edge portion of the substrate to place the substrate on the plurality of support pins, and also presses the tapered surfaces of the plurality of grippers against the edge portion of the substrate to bring the substrate in spaced apart relation to the plurality of support pins, thereby causing the plurality of grippers to grip the substrate.

Preferably, the substrate processing apparatus further comprises a processing liquid supply part for supplying a processing liquid to the surface of the substrate held in the horizontal position by the gripping part.

More preferably, the substrate processing apparatus further comprises a gas supply part for supplying a gas to the surface of the substrate.

According to another aspect of the present invention, the substrate processing apparatus comprises: a substrate rest part for placing a substrate in an inclined position thereon; a gripping part for bringing the substrate placed on the substrate rest part into spaced apart relation to the substrate rest part to hold the substrate in a horizontal position; and a substrate rotating mechanism for rotating the substrate held in the horizontal position by the gripping part.

The placement of the substrate allows the processing liquid to be removed from the surface of the substrate by gravity. Holding and rotating the substrate with the processing liquid removed from the surface thereof in the horizontal position prevent the occurrence of water marks to achieve good drying of the surface of the substrate.

Preferably, the substrate processing apparatus further comprises a processing liquid supply part for supplying a processing liquid to the surface of the substrate held in the horizontal position by the gripping part.

More preferably, the substrate processing apparatus further comprises a gas supply part for supplying a gas to the surface of the substrate.

The present invention is also intended for a method of removing a processing liquid from a surface of a substrate to dry the substrate.

According to the present invention, the method comprises the steps of: a) placing a substrate with a processing liquid remaining on a surface thereof in an inclined position thereon; b) changing the position of the substrate placed in the inclined position to hold the substrate in a horizontal position; and c) rotating the substrate held in a horizontal position after changing the position of the substrate.

The placement of the substrate allows the processing liquid to be removed from the surface of the substrate by gravity. Holding and rotating the substrate with the processing liquid removed from the surface thereof in the horizontal position prevent the occurrence of water marks to achieve good drying of the surface of the substrate.

The substrate placed in the step of placing the substrate (the step a)) is in the inclined position. Thus, there is no need to provide the step of raising an edge portion of the substrate and the like to place the substrate in the inclined position. This prevents the decrease in throughput of substrate processing.

Preferably, the method further comprises the step of d) supplying the processing liquid to the surface of the substrate held in the horizontal position, the step d) being executed before the step a).

More preferably, the method further comprises the step of e) transporting the substrate to which the processing liquid is supplied in a horizontal position from a first processing part to a second processing part, the step e) being executed in the first processing part after the step d), the step a) being executed in the second processing part.

More preferably, the step b) is executed after the processing liquid is removed from the surface of the substrate placed in the inclined position in the step a) so that at least the center of the substrate becomes an exposed region from which the processing liquid is removed.

More preferably, the method further comprises the step of f) supplying a gas to the surface of the substrate, the step f) being started after the processing liquid is removed from the surface of the substrate placed in the inclined position in the step a) so that at least the center of the substrate becomes the exposed region from which the processing liquid is removed.

It is therefore an object of the present invention to provide a substrate processing apparatus capable of preventing the occurrence of water marks to dry a substrate surface well by the use of a simple structure.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing the overall construction of a substrate processing apparatus;

FIG. 2 is a plan view of a spinning base;

FIGS. 3A and 3B are sectional views of the spinning base;

FIGS. 4A, 4B and 4C are side views of a chuck pin;

FIG. 5 is a plan view showing the layout of a motion conversion mechanism provided in the spinning base;

FIG. 6 is a sectional view of the spinning base showing the layout of a chuck pin drive mechanism;

FIG. 7 is a plan view of the spinning base showing the layout of the chuck pin drive mechanism;

FIG. 8 is a plan view showing the construction of a non-rotating movable member;

FIG. 9 is a perspective view of a linkage mechanism constituting the motion conversion mechanism;

FIG. 10 is a partial sectional view showing the construction of the chuck pin;

FIG. 11 is a flow diagram showing a procedure of execution of processes on a substrate in the substrate processing apparatus;

FIGS. 12A, 12B, 13A, 13B and 13C are sectional views of the spinning base in respective steps during the execution of the processes; and

FIGS. 14A and 14B are sectional views of the spinning base.

### DESCRIPTION OF THE PREFERRED EMBODIMENTS

### First Preferred Embodiment

<1. Construction>

<1-1. Overall Construction of Substrate Processing Apparatus 100>

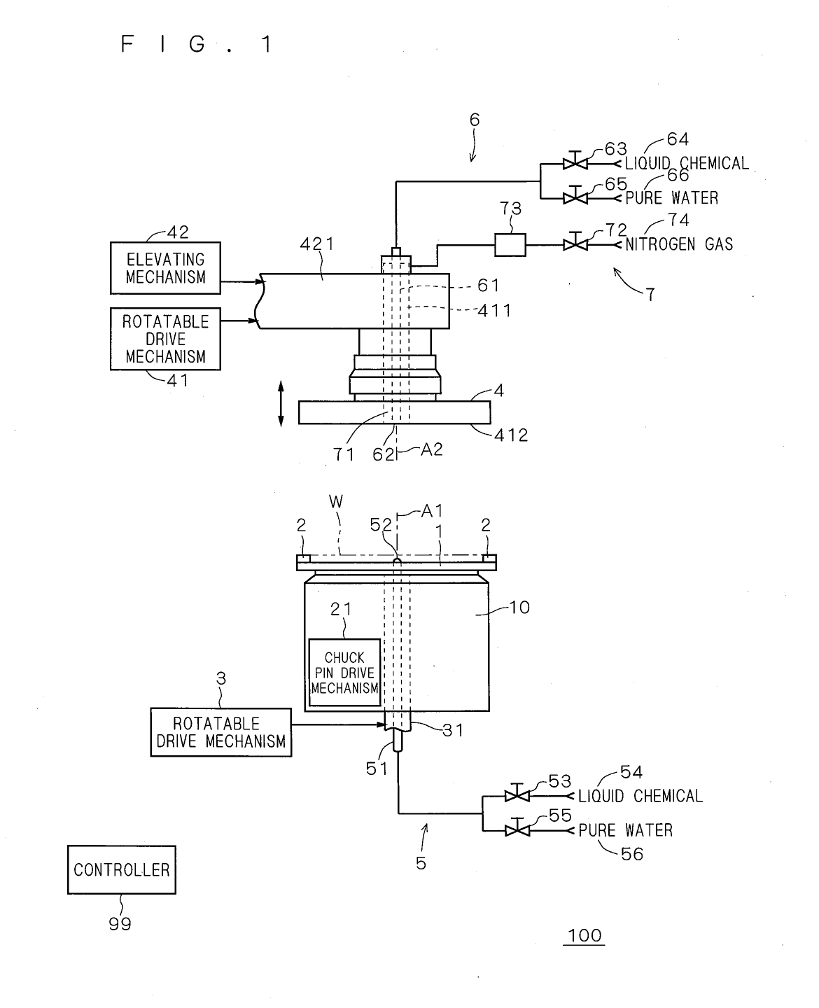

The construction of a substrate processing apparatus 100 according to a first preferred embodiment of the present invention will be described with reference to FIG. 1. FIG. 1 is a view showing the overall construction of the substrate processing apparatus 100 according to the first preferred embodiment.

The substrate processing apparatus 100 is a single wafer type processing apparatus which supplies a predetermined processing liquid (a liquid chemical such as a chemical agent or an organic solvent, and a rinsing liquid such as pure water or deionized water) to a substrate W to sequentially perform predetermined processes (a liquid chemical process, a rinsing process and the like) on the substrate W and which further performs a drying process on the substrate W subjected to the rinsing process (i.e., performs the process of removing the rinsing liquid from the surface of the substrate W to dry the substrate W).

The substrate processing apparatus 100 includes a spinning base 1, chuck pins 2a, 2b and 2c (referred to simply as “chuck pins 2,” unless otherwise identified), a rotatable drive mechanism 3, a barrier plate 4, a lower surface processing liquid supply system 5, an upper surface processing liquid supply system 6, and a gas supply system 7.

The substrate processing apparatus 100 further includes a controller 99 constructed by a computer including a CPU, a memory and the like. The controller 99 is electrically connected to the rotatable drive mechanism 3, a chuck pin drive mechanism 21, a rotatable drive mechanism 41, an elevating mechanism 42, valves 53, 55, 63, 65, 72 and the like, and controls the operations thereof.

A spin chuck 10 constructed by the spinning base 1, the chuck pins 2, the rotatable drive mechanism 3 and the like holds a substrate W substantially horizontally in such a manner that a surface of the substrate W on which a device is to be formed is positioned to face upward, and rotates the substrate W held thereon in a horizontal plane about an axis A1 extending in a vertical direction (a vertical axis passing through substantially the center of the substrate W).

The spinning base 1 is a support table for rotatably supporting a substrate W. More specifically, the spinning base 1 is a generally disk-shaped member fixed on an upper end of a rotary shaft 31 rotated by the rotatable drive mechanism 3, and the plurality of chuck pins 2 are provided on the upper surface of the spinning base 1.

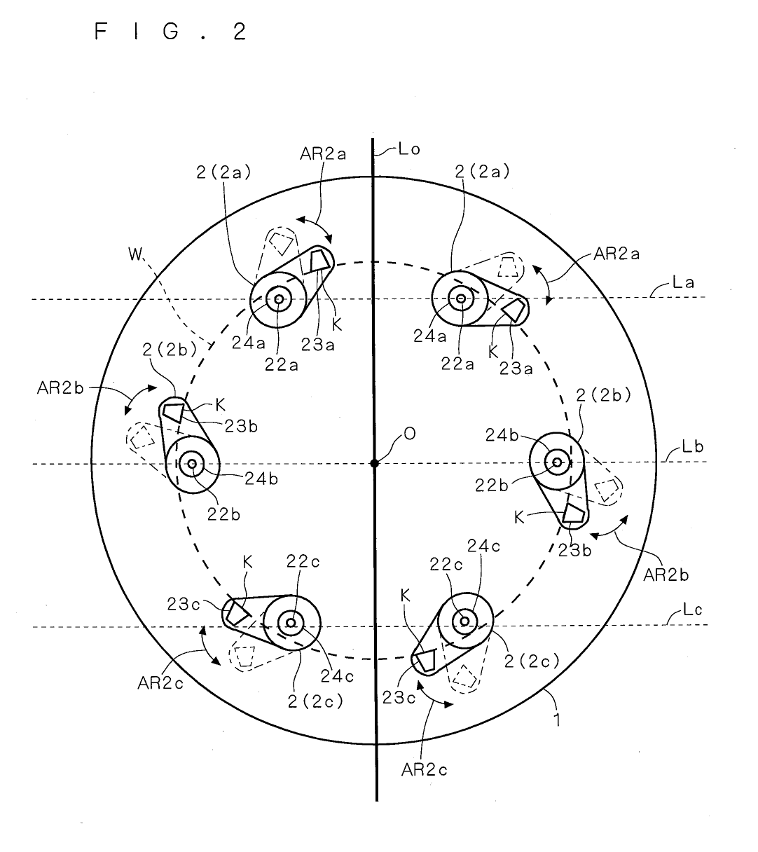

The plurality of chuck pins 2 are provided in predetermined locations on the upper surface of the spinning base 1 (see FIG. 2). The plurality of chuck pins 2 (more specifically, support pins 22a, 22b and 22c provided in the respective chuck pins 2) collectively function as a substrate rest part for placing a substrate W in an inclined position thereon. Additionally, the chuck pins 2 (more specifically, substrate gripping parts 23a, 23b and 23c provided in the respective chuck pins 2) collectively function as a gripping part for gripping an edge portion of the substrate W placed in an inclined position to separate the substrate W from the substrate rest part, thereby holding the substrate W in a horizontal position in spaced apart relation to the substrate rest part. The plurality of chuck pins 2 are pivotably driven (as indicated by arrows AR2a, AR2b and AR2c shown in FIG. 2) in cooperation with each other by the chuck pin drive mechanism 21 to change between a releasing state (indicated by phantom lines in FIG. 2) in which the chuck pins 2 function as the substrate rest part and a gripping state (indicated by solid lines in FIG. 2) in which the chuck pins 2 function as the gripping part. At least three chuck pins 2 are only needed to hold the circular substrate W with reliability. In the substrate processing apparatus 100 according to the first preferred embodiment, six chuck pins 2 shall be positioned upright at equally spaced intervals (at 60° intervals) along the periphery of the spinning base 1. The specific construction of the chuck pins 2 will be described in detail later.

The rotatable drive mechanism 3 includes an electric motor, and a torque transmission mechanism for transmitting the rotation of the electric motor to the rotary shaft 31. The rotatable drive mechanism 3 is capable of rotating the rotary shaft 31, the spinning base 1 and the substrate W held by the chuck pins 2 about the vertical axis A1 in a horizontal plane. The rotatable drive mechanism 3 used herein may employ a hollow motor having a motor shaft direct-coupled to the rotary shaft 31. The rotary shaft 31 is a hollow shaft having an interior through which a lower surface processing liquid supply pipe 51 is inserted.

The barrier plate 4 is a generally disk-shaped member fixed to a lower end of a rotary shaft 411 rotated by the rotatable drive mechanism 41, and has a substrate-facing surface 412 opposed to the upper surface of the substrate W held by the spin chuck 10 and having a diameter slightly greater than that of the substrate W. The rotary shaft 411 extends along an axis A2 in common with the axis A1 of the rotary shaft 31. The rotary shaft 411 is a hollow shaft having an interior through which an upper surface processing liquid supply pipe 61 is inserted. The barrier plate 4 is movable upwardly and downwardly in a vertical direction by the elevating mechanism 42.

The rotatable drive mechanism 41 includes an electric motor, and a torque transmission mechanism for transmitting the rotation of the electric motor to the rotary shaft 411. The rotatable drive mechanism 41 is capable of rotating the rotary shaft 411 and the barrier plate 4 about the vertical axis A2 in a horizontal plane. In other words, the barrier plate 4 is rotated in substantially parallel and coaxial relation to the substrate W held by the spin chuck 10. The barrier plate 4 is rotated at approximately the same rpm and in the same direction as the substrate W held by the spin chuck 10.

The elevating mechanism 42 includes, for example, a feed screw mechanism employing a ball screw, a mechanism employing an air cylinder and the like. The elevating mechanism 42 causes a support arm 421 to receive the rotary shaft 411, the barrier plate and the rotatable drive mechanism 41 therein, and moves the support arm 421 entirely upwardly and downwardly, to thereby integrally moving the rotary shaft 411, the barrier plate 4 and the rotatable drive mechanism 41 upwardly and downwardly. More specifically, the elevating mechanism 42 moves the substrate-facing surface 412 of the barrier plate 4 upwardly and downwardly between a first position at which the substrate-facing surface 412 is in close proximity to the upper surface of the substrate W held by the spin chuck 10 and a second position at which the substrate-facing surface 412 is greatly upwardly spaced apart from the upper surface of the substrate W. When the barrier plate 4 is in close proximity to the upper surface of the substrate W held by the spin chuck 10, the barrier plate 4 covers the entire surface of the substrate W.

The lower surface processing liquid supply system 5 supplies a processing liquid toward a lower surface of the substrate W. The lower surface processing liquid supply system 5 includes the lower surface processing liquid supply pipe 51, a lower surface nozzle 52, the liquid chemical valve 53, a liquid chemical supply source 54, the pure water valve 55, and a pure water supply source 56.

The lower surface processing liquid supply pipe 51 is inserted through the interior of the rotary shaft 31, and extends to a position in close proximity to the center of the lower surface of the substrate W held by the spin chuck 10 so as to have a first end formed with the lower surface nozzle 52 for ejecting a processing liquid toward the center of the lower surface of the substrate W. The lower surface processing liquid supply pipe 51 has a second end connected through the liquid chemical valve 53 to the liquid chemical supply source 54 which stores a predetermined liquid chemical. Examples of the predetermined liquid chemical stored in the liquid chemical supply source 54 include hydrofluoric acid (HF), buffered hydrofluoric acid (BHF), an SC-b 1 (standard cleaning 1; NH₄OH—H₂O₂—H₂O) solution which is a liquid mixture of aqueous ammonia, a hydrogen peroxide solution and water), an SC-2 (standard cleaning 2; HCl—H₂O₂—H₂O) solution which is a liquid mixture of hydrochloric acid, a hydrogen peroxide solution and water), and the like. The second end of the lower surface processing liquid supply pipe 51 is also connected through the pure water valve 55 to the pure water supply source 56 which stores a predetermined rinsing liquid (for example, deionized pure water). The controller 99 controls the opening and closing of the liquid chemical valve 53 to cause the lower surface nozzle 52 to eject the predetermined liquid chemical therefrom. The controller 99 also controls the opening and closing of the pure water valve 55 to cause the lower surface nozzle 52 to eject the pure water therefrom.

The upper surface processing liquid supply system 6 supplies a processing liquid toward the upper surface of the substrate W. The upper surface processing liquid supply system 6 includes the upper surface processing liquid supply pipe 61, an upper surface nozzle 62, the liquid chemical valve 63, a liquid chemical supply source 64, the pure water valve 65, and a pure water supply source 66.

The upper surface processing liquid supply pipe 61 is inserted through the interior of the rotary shaft 411, and has a first end formed with the upper surface nozzle 62 for ejecting a processing liquid toward the center of the upper surface of the substrate W. The upper surface processing liquid supply pipe 61 has a second end connected through the liquid chemical valve 63 to the liquid chemical supply source 64 which stores a predetermined liquid chemical. The second end of the upper surface processing liquid supply pipe 61 is also connected through the pure water valve 65 to the pure water supply source 66 which stores a predetermined rinsing liquid. The controller 99 controls the opening and closing of the liquid chemical valve 63 to cause the upper surface nozzle 62 to eject the predetermined liquid chemical therefrom. The controller 99 also controls the opening and closing of the pure water valve 65 to cause the upper surface nozzle 62 to eject the pure water therefrom.

The gas supply system 7 ejects and supplies a predetermined gas (an inert gas which shall be nitrogen gas in the first preferred embodiment) to the upper surface of the substrate W. The gas supply system 7 includes a gas supply passage 71, the gas valve 72, a flow regulating part 73, and a gas supply source 74.

The gas supply passage 71 is formed between an inner wall surface of the rotary shaft 411 and an outer wall surface of the upper surface processing liquid supply pipe 61. The gas supply passage 71 is connected through the gas valve 72 and the flow regulating part 73 to the gas supply source 74 which supplies nitrogen gas. The controller 99 controls the opening and closing of the gas valve 72 to cause the gas supply passage 71 to eject the nitrogen gas therefrom. The controller 99 also controls the flow regulating part 73 to change the flow rate of the nitrogen gas ejected from the gas supply passage 71.

<1-2. Chuck Pins 2>

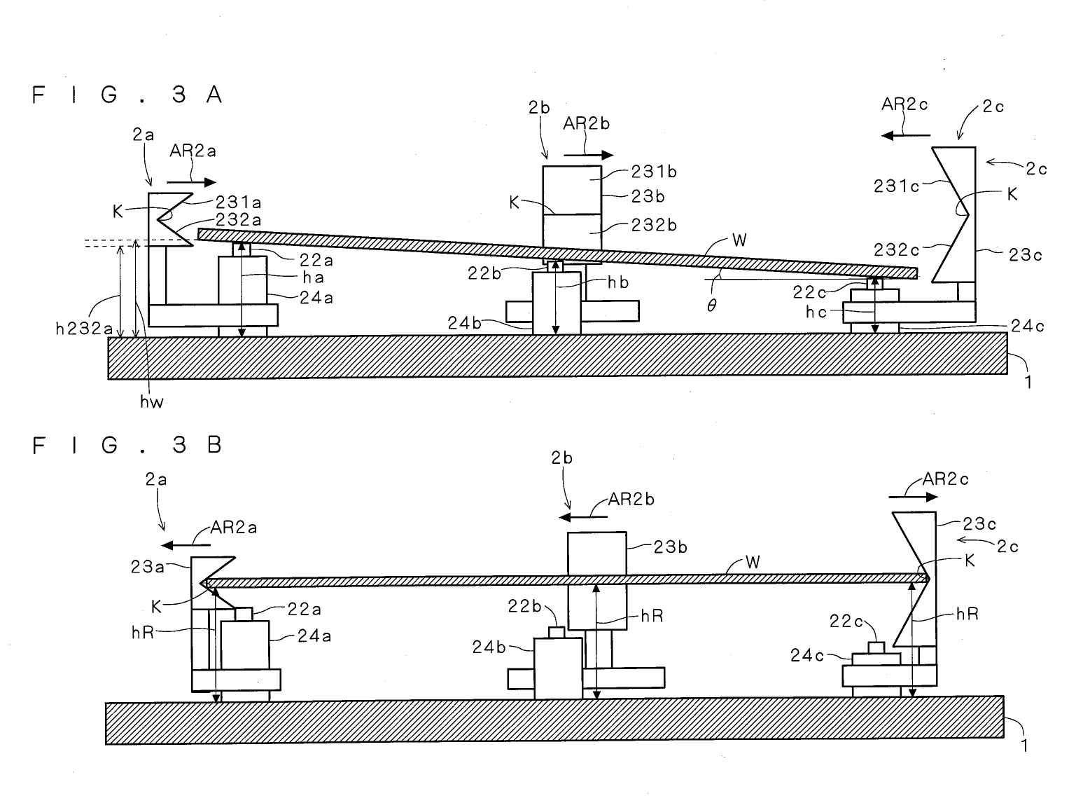

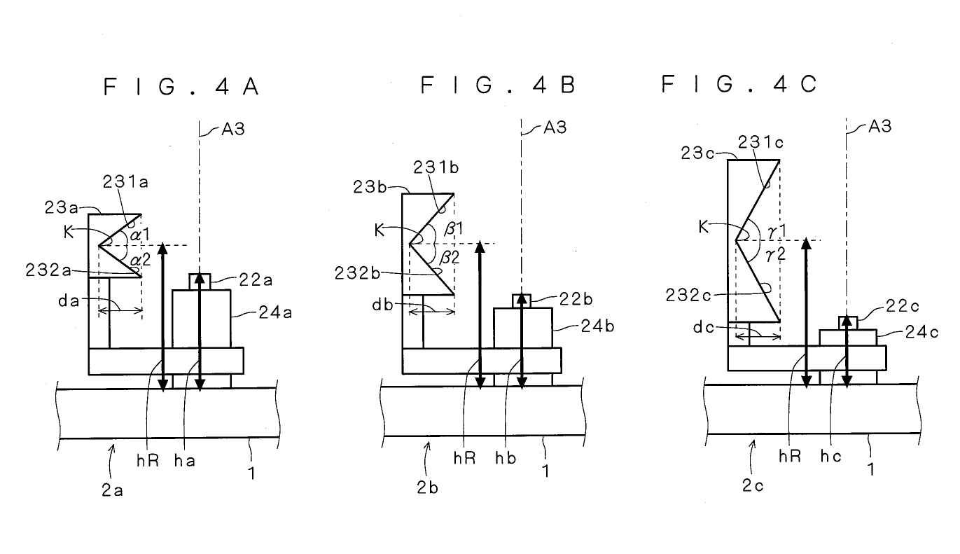

The chuck pins 2a, 2b and 2c will be described in further detail with reference FIGS. 2, 3A, 3B, 4A, 4B and 4C. FIG. 2 is a plan view of the spinning base 1. FIGS. 3A and 3B are sectional views of the spinning base 1 (taken along the line Lo of FIG. 2). FIGS. 4A to 4C are side views of the chuck pins 2a, 2b and 2c, respectively.

<Arrangement of Chuck Pins 2a, 2b and 2c>

With reference to FIG. 2, the spinning base 1 is provided with three pairs of chuck pins 2, i.e. six chuck pins 2, which are arranged at equally spaced intervals along the periphery of the spinning base 1, as mentioned above. More specifically, the chuck pins 2a, 2b and 2c are provided so that the support pins 22a, 22b and 22c of the chuck pins 2a, 2b and 2c are positioned on contour axes La, Lb and Lc, respectively, which are parallel with each other and perpendicular to the inclined axis Lo passing through the center O of the spinning base 1, as shown in FIG. 2.

The chuck pins 2a, 2b and 2c are disposed so that the innermost edges K of the V-shaped cross-sectional recesses of the substrate gripping parts 23a, 23b and 23c of the chuck pins 2a, 2b and 2c are positioned in parallel with a direction tangent to the substrate W when the substrate gripping parts 23a, 23b and 23c are placed at a gripping position (indicated by solid lines in FIG. 2) to be described later.

<Construction of Chuck Pins 2a, 2b and 2c>

With reference to FIGS. 4A to 4C, the chuck pins 2a, 2b and 2c include the respective support pins 22a, 22b and 22c for supporting the periphery of the substrate W by making point contact therewith from below, and the respective substrate gripping parts 23a, 23b and 23c serving as grippers provided in a one-to-one correspondence with the support pins 22a, 22b and 22c and for sidewise pressing the peripheral edge of the substrate W to grip the peripheral edge of the substrate W. The support pins 22a, 22b and 22c and the substrate gripping parts 23a, 23b and 23c are provided on generally cylindrical movable body members 24a, 24b and 24c, respectively, which are rotatable bases supported rotatably on vertical axes A3 passing through the centers of the support pins 22a , 22b and 22c.

Each of the support pins 22a has a tip positioned at a height (referred to hereinafter as a “first height ha”) which is spaced the predetermined distance ha apart from the surface of the spinning base 1 which is a horizontal surface. That is, the pair of support pins 22a support the substrate W at the first height ha on the contour axis La (as shown in FIG. 3A).

Each of the support pins 22b has a tip positioned at a height (referred to hereinafter as a “second height hb”) which is spaced the predetermined distance hb (where the distance hb<the distance ha) apart from the surface of the spinning base 1. That is, the pair of support pins 22b support the substrate W at the second height hb on the contour axis Lb.

Each of the support pins 22c has a tip positioned at a height (referred to hereinafter as a “third height hc”) which is spaced the predetermined distance hc (where the distance hc<the distance hb) apart from the surface of the spinning base 1. That is, the pair of support pins 22c support the substrate W at the third height hc on the contour axis Lc.

The substrate gripping parts 23a, 23b and 23c are provided on the movable body members 24a, 24b and 24c at eccentric positions relative to the rotation centers (the vertical axes A3) of the movable body members 24a, 24b and 24c, respectively. Thus, the movable body members 24a, 24b and 24c are driven by the chuck pin drive mechanism 21 to rotate about the positions of the respective support pins 22a, 22b and 22c, thereby causing the substrate gripping parts 23a, 23b and 23c to move toward and away from the substrate W (as indicated by the arrows AR2a, AR2b and AR2c). This enables the substrate gripping parts 23a, 23b and 23c to change between a gripping position (the position indicated by solid lines in FIG. 2; and the position shown in FIG. 3B) at which the substrate gripping parts 23a, 23b and 23c press the peripheral edge of the substrate W to form a pressing state (or a gripping state) and a releasing position (the position indicated by phantom lines in FIG. 2; and the position shown in FIG. 3A) at which the substrate gripping parts 23a, 23b and 23c are separated from the peripheral edge of the substrate W to form an open state (or a releasing state).

Each of the substrate gripping parts 23a is a member having a pair of tapered surfaces of a V-shaped cross-sectional configuration which receive the edge of the substrate W. The pair of tapered surfaces are as follows: an upper inclined surface 231a inclined at an elevation angle α1 and a lower inclined surface 232a inclined at a depression angle α2 (where α2=α1). Changing from the releasing position to the gripping position causes the substrate gripping parts 23a to move toward the substrate W so that the tapered surfaces thereof grip the substrate W therebetween while raising the substrate W. Specifically, as shown in FIGS. 3A and 3B, as the substrate gripping parts 23a move from the releasing position to the gripping portion, the substrate W slides upwardly while the lower edge surface of the substrate W makes sliding contact with the lower inclined surface 232a. Finally, the substrate W is fixedly gripped by the substrate gripping parts 23a, with the upper edge surface of the substrate W in contact with the upper inclined surface 231a and the lower edge surface thereof in contact with the lower inclined surface 232a.

Like the substrate gripping parts 23a, each of the substrate gripping parts 23b is a member having a pair of tapered surfaces of a V-shaped cross-sectional configuration which receive the edge of the substrate W. The pair of tapered surfaces are as follows: an upper inclined surface 231b inclined at an elevation angle β1 and a lower inclined surface 232b inclined at a depression angle β2 (where β2=β1). Changing from the releasing position to the gripping position causes the substrate gripping parts 23b to move toward the substrate W so that the tapered surfaces thereof grip the substrate W therebetween while raising the substrate W.

Like the substrate gripping parts 23a, each of the substrate gripping parts 23c is a member having a pair of tapered surfaces of a V-shaped cross-sectional configuration which receive the edge of the substrate W. The pair of tapered surfaces are as follows: an upper inclined surface 231c inclined at an elevation angle γ1 and a lower inclined surface 232c inclined at a depression angle γ2 (where γ2=γ1). Changing from the releasing position to the gripping position causes the substrate gripping parts 23c to move toward the substrate W so that the tapered surfaces thereof grip the substrate W therebetween while raising the substrate W.

The innermost edges K of the V-shaped cross-sectional recesses of the substrate gripping parts 23a, 23b and 23c are positioned at a height (referred to hereinafter as a “gripping height hR”) which is spaced the predetermined distance hR (where the distance hR>the distance ha) apart from the surface of the spinning base 1. That is, the substrate gripping parts 23a, 23b and 23c fix and hold the substrate W at the gripping height hR at their gripping position.

The height h232a of the lower end edge of the lower inclined surface 232a of each of the substrate gripping parts 23a is lower than the height hW of the lower surface of the substrate W supported at the first height ha (as shown in FIG. 3A) so that the substrate gripping parts 23a grip and raise the substrate W placed on the support pins 22a with reliability. Similar considerations apply to the substrate gripping parts 23b and 23c.

The maximum depths da, db and dc of the V-shaped cross-sectional recesses of the substrate gripping parts 23a, 23b and 23c (i.e., horizontal distances da, db and dc between the innermost edges K and the lower end edges of the lower inclined surfaces 232a, 232b and 232c) are set at values equal to each other. The angles are set to satisfy the following: α1 (α2)<β1 (β2)<γ1 (γ2). Such settings allow the distances the substrate gripping parts 23a, 23b and 23c moved from the gripping position to the releasing position to be equal to each other.

As discussed above, when the substrate gripping parts 23a, 23b and 23c are at the releasing position, the substrate gripping parts 23a, 23b and 23c are spaced apart from the edge of the substrate W, and the support pins 22a, 22b and 22c at the heights differing from each other support the substrate W to thereby support the substrate W in an inclined position (as shown in FIG. 3A). In other words, the chuck pins 2a, 2b and 2c collectively function as the substrate rest part for placing the substrate W in an inclined position in this case. It is desirable that the angle θ of inclination of the substrate W placed on the chuck pins 2a, 2b and 2c is sufficient for the movement of a liquid mass P covering the substrate W placed in an inclined position in a downward direction over the substrate W without breaking up into smaller masses. The angle θ of inclination is set within the range of 0.03 to 1 degree, preferably at 0.3 degree.

When the substrate gripping parts 23a, 23b and 23c are at the gripping position, the tapered surfaces of the substrate gripping parts 23a, 23b and 23c press the edge of the substrate W, grip the substrate W placed on the support pins 22a, 22b and 22c sidewise therebetween to raise and separate the substrate W from the surface rest part, and grip and hold the substrate W in a horizontal position at the gripping height hR (as shown in FIG. 3B). In other words, the chuck pins 2a, 2b and 2c function as the gripping part for holding the substrate W in a horizontal position in this case.

<1-3. Construction of Chuck Pin Drive Mechanism 21>

The chuck pin drive mechanism 21 is provided in the spinning base 1, and drives the six chuck pins 2 to pivot (more specifically, drives the movable body members 24a, 24b and 24c of the chuck pins 2 to rotate) in cooperation with each other. The chuck pins 2 are driven to pivot, thereby changing between the gripping state in which the substrate gripping parts 23a, 23b and 23c are at the gripping position and the releasing state in which the substrate gripping parts 23a, 23b and 23c are at the releasing position.

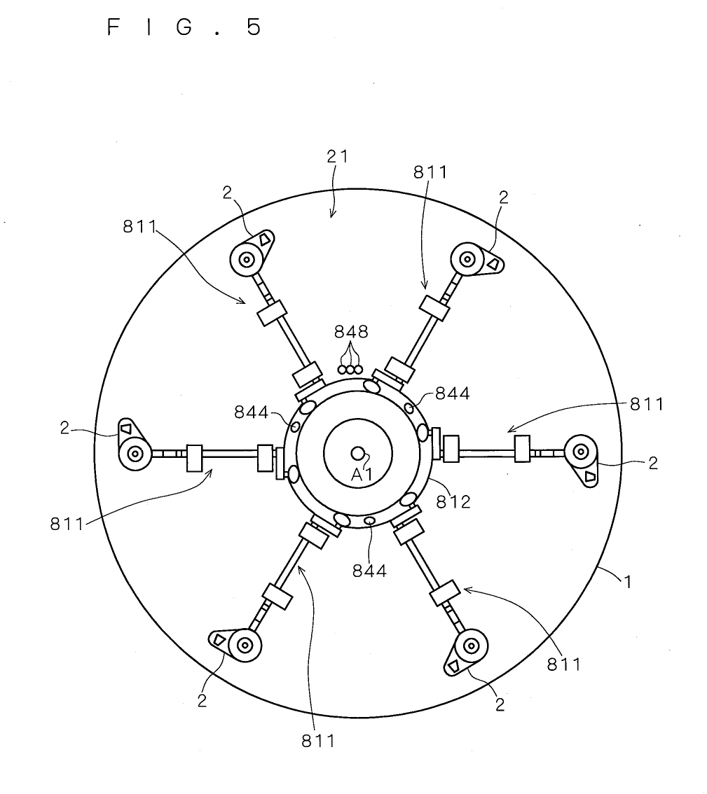

The chuck pin drive mechanism 21 will be specifically described with reference to FIGS. 5 to 10. FIGS. 5 to 10 are views for illustrating the layout of the chuck pin drive mechanism 21 provided in the spinning base 1. The substrate gripping parts 23a, 23b and 23c are referred to simply as “substrate gripping parts 23” hereinafter, unless otherwise identified. The support pins 22a, 22b and 22c are referred to simply as “support pins 22” hereinafter, unless otherwise identified. The movable body members 24a, 24b and 24c are referred to simply as “movable body members 24” hereinafter, unless otherwise identified.

FIG. 5 is a plan view showing the layout of a motion conversion mechanism provided in the spinning base 1. With reference to FIG. 5, the chuck pin drive mechanism 21 includes a plurality of linkage mechanisms 811 connected to the plurality of chuck pins 2, respectively, and a cooperating ring 812 for operating the plurality of linkage mechanisms 811 in cooperation with each other.

The cooperating ring 812 is a generally annular member disposed concentrically with the rotary shaft 31 of the spinning base 1. The cooperating ring 812 is moved upwardly and downwardly along the rotation axis A1 of the spinning base 1 by a cooperating ring elevating mechanism to be described later. The linkage mechanisms 811 constitute a motion conversion mechanism for converting the vertical motion of the cooperating ring 812 into the pivotal motion of the chuck pins 2. That is, the cooperating ring elevating mechanism moves the cooperating ring 812 upwardly and downwardly, and the motion conversion mechanism converts the vertical motion of the cooperating ring 812 into the rotational motion of the movable body members 24, whereby the position of the substrate gripping parts 23 is changed between the gripping position and the releasing position.

<Cooperating Ring Elevating Mechanism>

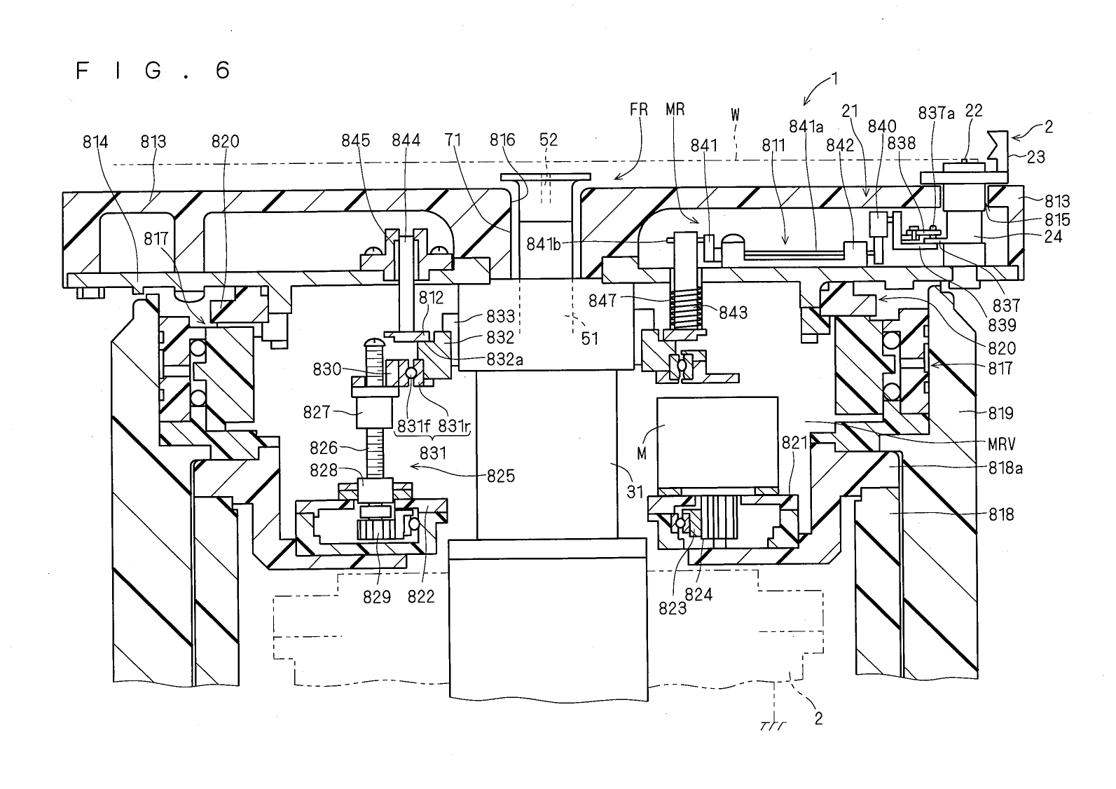

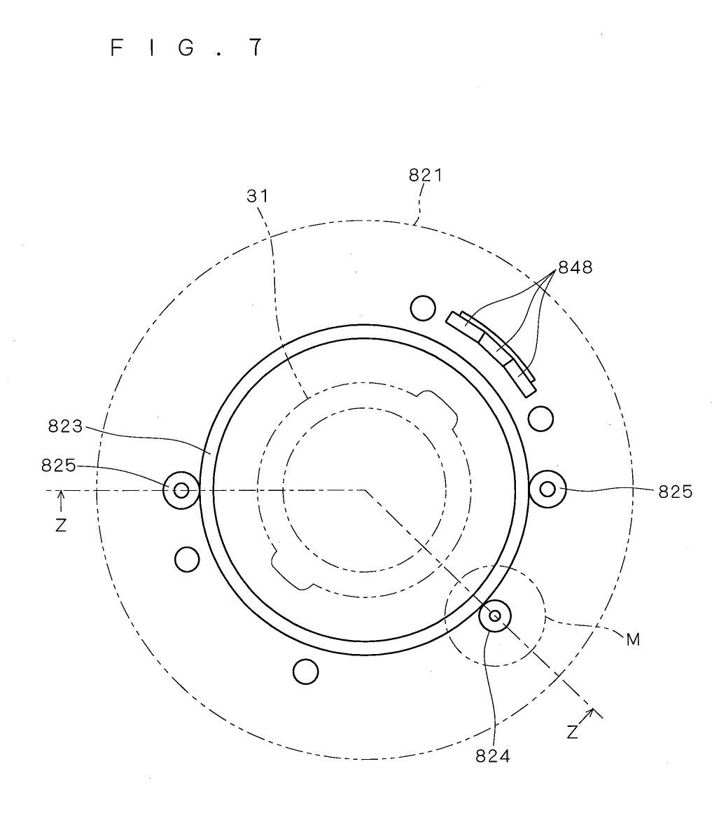

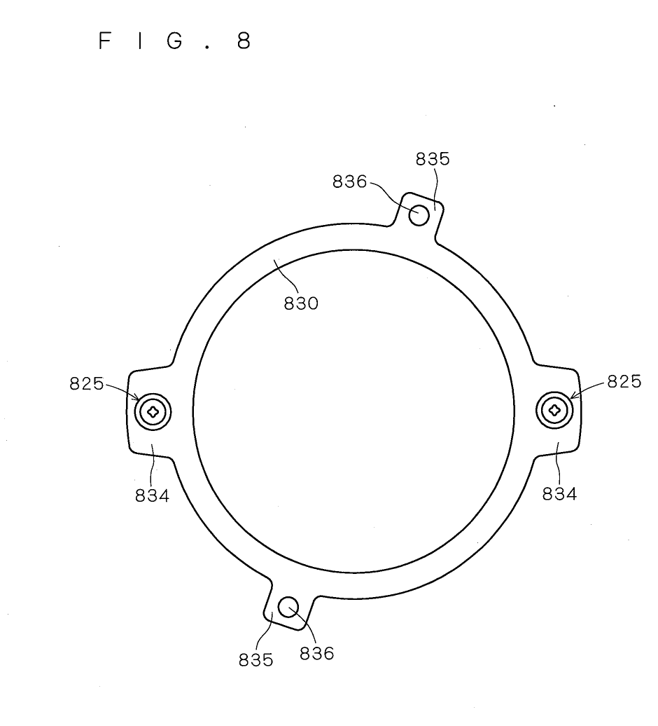

The cooperating ring elevating mechanism will be described with reference to FIGS. 6 to 8. FIG. 6 is a sectional view of the spinning base 1 showing the layout of the chuck pin drive mechanism 21 (a sectional view taken along the lines Z-Z of FIG. 7). FIG. 7 is a plan view of the spinning base 1 showing the layout of the chuck pin drive mechanism 21. FIG. 8 is a plan view showing the construction of a non-rotating movable member 830.

The spinning base 1 is constructed by securing an upper plate 813 and a lower plate 814 by bolting. A peripheral portion of the upper plate 813 is formed with through holes 815 for movably receiving the chuck pins 2.

A mechanism space MR for accommodating the motion conversion mechanism is defined between the upper plate 813 and the lower plate 814. A through hole 816 extending through the spinning base 1 is formed in the central portions of the upper plate 813 and the lower plate 814. The above-mentioned lower surface processing liquid supply pipe 51 is disposed so as to pass through the through hole 816 and to be inserted through the rotary shaft 31 of the spinning base 1. The above-mentioned lower surface nozzle 52 is fixed to the upper end of the lower surface processing liquid supply pipe 51.

A mechanical part accommodating space MRV cut off from the external atmosphere is defined between a sealing mechanism 817 and the rotary shaft 31. The sealing mechanism 817 is disposed on an inner surface near an upper end of a tubular cover member 819 surrounding a casing 818 which surrounds the rotatable drive mechanism 3, the upper end of the cover member 819 being configured to extend to near the lower surface of the spinning base 1. The sealing mechanism 817 is in sliding contact with a sealing member 820 fixed to the lower surface of the spinning base 1. This allows the mechanical part accommodating space MRV defined between the sealing mechanism 817 and the rotary shaft 31 to become a space cut off from the external atmosphere.

In the mechanical part accommodating space MRV, an annular gear case 821 surrounding the rotary shaft 31 is mounted on a top cover 818a of the casing 818. A motor M is fixed on the gear case 821. Inside the gear case 821, bearings 822 are pressed into the inner and outer peripheral portions of the inner wall of the gear case 821. The bearings 822 are disposed in coaxial relation to the rotary shaft 31. A ring-shaped gear 823 surrounding the rotary shaft 31 is fixed to a rotating ring of each of the bearings 822. Thus, the gear 823 is rotatable in coaxial relation to the rotary shaft 31 inside the gear case 821. The gear 823 has gear teeth on an outer periphery thereof.

A pinion 824 fixed to a driving shaft of the motor M is in meshing engagement with the gear 823 (as illustrated in FIG. 7). A pair of ball screw mechanisms 825 are disposed on the gear case 821 at positions clear of the motor M and circumferentially opposed to each other with respect to the rotary shaft 31 (or lateral to the rotary shaft 31), as shown in FIG. 7.

Each of the ball screw mechanisms 825 includes a threaded shaft 826 disposed parallel with the rotary shaft 31, and a ball nut 827 in threaded engagement with the threaded shaft 826. The threaded shaft 826 is mounted through a bearing portion 828 to a top cover of the gear case 821, and has a lower end extending to the interior of the gear case 821. A gear 829 is fixed to the lower end of the threaded shaft 826, and is in meshing engagement with the gear 823.

The non-rotating movable member 830 is mounted to the ball nut 827. The non-rotating movable member 830 is an annular member surrounding the rotary shaft 31, and has an inner peripheral surface to which a non-rotating ring 831f of a bearing 831 provided so as to surround the rotary shaft 31 is fixed. A rotating ring 831r of the bearing 831 is inwardly of the non-rotating ring 831f with respect to the rotary shaft 31. The rotating ring 831r is fixed to an outer peripheral surface of an annular rotating movable member 832 surrounding the rotary shaft 31. The rotating movable member 832 is in engagement with a guide rail 833 protruding from the outer peripheral surface of the rotary shaft 31. The guide rail 833 is formed to extend in a direction parallel with the rotary shaft 31. Thus, the rotating movable member 832 is coupled to the rotary shaft 31 in such a manner as to be guided and movable along the rotary shaft 31.

As the motor M is driven to rotate the pinion 824, the rotation of the pinion is transmitted to the gear 823. This causes the gear 829 in meshing engagement with the gear 823 to rotate, thereby rotating the threaded shaft 826 of each of the ball screw mechanisms 825. This causes the ball nut 827 and the non-rotating movable member 830 coupled to the ball nut 827 to move vertically along the rotary shaft 31. Since the rotating movable member 832 which rotates with the rotary shaft 31 is coupled through the bearing 831 to the non-rotating movable member 830, the rotating movable member 832 is moved vertically along the guide rail 833 by the vertical movement of the non-rotating movable member 830 even when the rotary shaft 31 is rotating.

As illustrated in FIG. 8, the non-rotating movable member 830 includes a pair of protrusions 834 protruding radially outwardly and formed at positions corresponding to the ball nuts 827 of the pair of ball screw mechanisms 825, respectively. The non-rotating movable member 830 further includes another pair of protrusions 835 formed at positions circumferentially deviated from the protrusions 834. A pair of guide shafts 836 extending along the rotary shaft 31 are coupled to the pair of protrusions 835. The guide shafts 836 are guided in a vertical direction along the rotary shaft 31. Thus, the non-rotating movable member 830 moves upwardly and downwardly along the rotary shaft 31 while being held in a horizontal position. As the non-rotating movable member 830 moves upwardly and downwardly along the rotary shaft 31, the rotating movable member 832 moves upwardly and downwardly along the guide rail 833, and the cooperating ring 812 also moves upwardly and downwardly which is disposed at a position engageable with a shoulder 832a formed in an outer peripheral portion of the rotating movable member 832.

<Motion Conversion Mechanism>

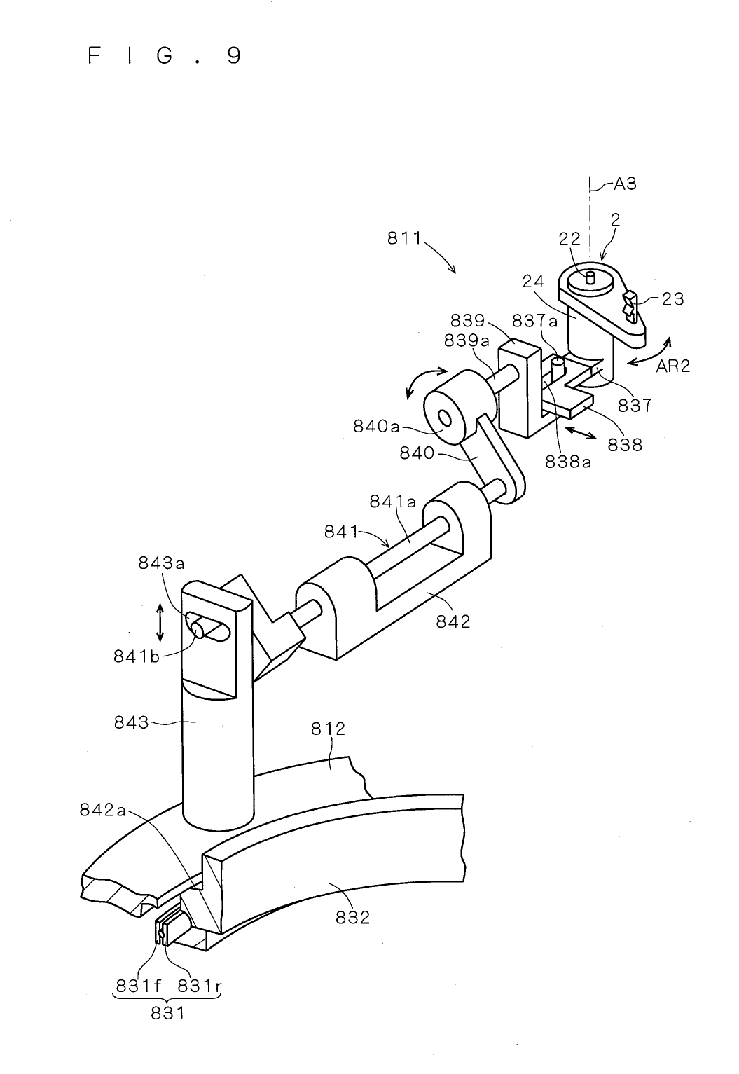

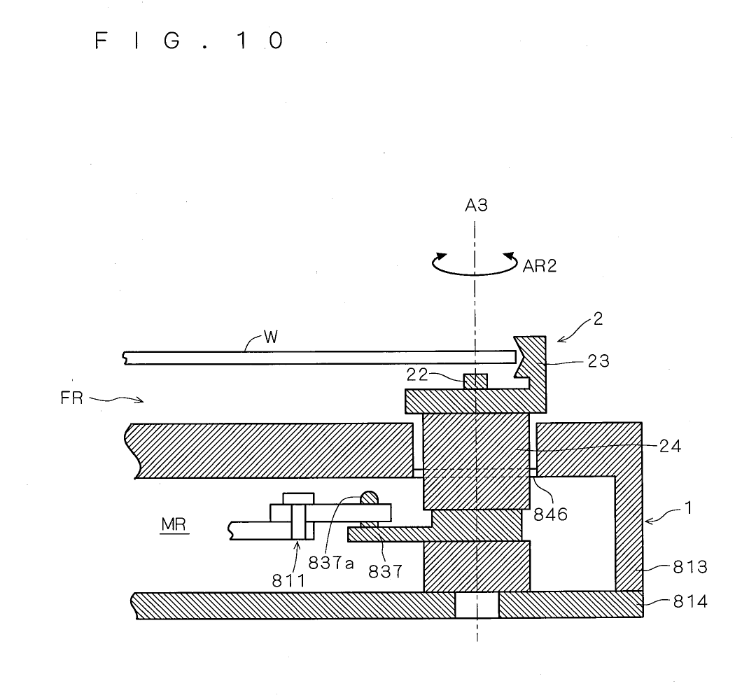

The motion conversion mechanism will be described with reference to FIGS. 9 and 10. FIG. 9 is a perspective view of the linkage mechanism 811 constituting the motion conversion mechanism. FIG. 10 is a partial sectional view showing the construction of each of the chuck pins 2.

As mentioned above, each of the chuck pins 2 includes the substantially cylindrical movable body member 24 supported rotatably about the vertical axis A3 passing through the center of the support pin 22. The movable body member 24 is rotatable by being inserted through the through hole 815, and the support pin 22 is disposed radially inwardly of the substrate W relative to a substrate-facing region FR.

A lever 837 protruding sidewise under the chuck pin 2 is fixed to the movable body member 24, and a pin 837a extending vertically upwardly is mounted upright on the tip of the lever 837. The linkage mechanism 811 includes the lever 837, a pivotal plate 838 having a slot 838a for engagement with the lever 837, a crank member 839 coupled to the pivotal plate 838, a lever 840 having a bearing portion 840a which rotatably supports a shaft portion 839a of the crank member 839, a crank member 841 coupled to the lever 840, a bearing member 842 which rotatably supports a first shaft portion 841a of the crank member 841, and an elevating member 843 having a slot 843a for engagement with a second shaft portion 841b of the crank member 841. The elevating member 843 has a lower end coupled to the upper surface of the cooperating ring 812. The cooperating ring 812 is disposed at a position engageable with the shoulder 832a formed in the outer peripheral portion of the rotating movable member 832.

As illustrated in FIG. 5, a plurality of (in this preferred embodiment, three) guide shafts 844 are disposed at equally spaced intervals and mounted upright on the upper surface of the cooperating ring 812 so as to extend vertically upwardly along the rotary shaft 31. As illustrated in FIG. 6, each of the guide shafts 844 extends through the lower plate 814 of the spinning base 1, and is held vertically movably by a bushing 845 provided within the spinning base 1. Thus, the cooperating ring 812 moves upwardly and downwardly along the rotary shaft 31 while assuming a horizontal position with the rotating movable member 832. Accordingly, as the elevating member 843 moves upwardly and downwardly, the crank member 841 rotates about the first shaft portion 841a supported by the bearing member 842. The slot 843a formed in the elevating member 843 extends in a horizontal direction. This causes the vertical motion of the elevating member 843 to be smoothly converted into the rotational motion of the crank member 841.

The lever 840 is pivoted by the rotation of the crank member 841 to move the crank member 839 supported by the bearing portion 840a of the lever 840 in a circumferential direction of the spinning base 1 as seen in plan view. The slot 838a formed in the pivotal plate 838 extends in a radial direction of the spinning base 1, and the pin 837a extending in a vertical direction is in engagement with the slot 838a. Thus, the pivotal plate 838 held in a horizontal position is pivoted while slightly moving upwardly and downwardly relative to the spinning base 1. As the pivotal plate 838 pivots, the pin 837a is displaced in a circumferential direction of the spinning base 1, to thereby cause the lever 837 to pivot the chuck pin 2 on the axis A3. In this manner, the linkage mechanisms 811 converts the vertical motion of the rotating movable member 832 into the rotational motion of the movable body member 24.

As the movable body member 24 is rotated about the vertical axis A3, the substrate gripping part 23 moves toward and away from the periphery of the substrate W to change between the gripping position and the releasing position. To place the substrate gripping part 23 at the releasing position, the controller 99 controls the motor M so that the cooperating ring 812 is at a raised position (or at the above-mentioned first height). To change the substrate gripping part 23 from the releasing position to the gripping position, the controller 99 controls the motor M, for example, to drive the ball screw mechanism 825, thereby moving the ball nut 827 downwardly. This moves the rotating movable member 832 downwardly to move the cooperating ring 812 downwardly. Thus, the elevating member 843 is moved downwardly under the spring force of a helical compression spring 847 and gravity. As a result, the chuck pin 2 pivots about the vertical axis A3, whereby the substrate gripping part 23 abuts against the peripheral edge of the substrate W to grip the substrate W.

A ring-shaped sealing member 846 is provided in a boundary portion (or movable portion) between the movable body member 24 and the through hole 815 formed in the upper plate 813 of the spinning base 1 to provide isolation between the mechanism space MR and the space extending from the through hole 815 to over the spinning base 1. The sealing member 846 is provided in a lower end portion of the movable portion, that is, a connecting portion between the mechanism space MR and the through hole 815, and prevents a processing liquid from flowing along the movable portion into the mechanism space MR by capillary action.

As illustrated in FIG. 6, the helical compression spring 847 is disposed on the elevating member 843 of the linkage mechanisms 811 between the lower surface of the lower plate 814 of the spinning base 1 and the upper surface of the cooperating ring 812. Thus, the cooperating ring 812 is urged downwardly. As a result, the substrate gripping part 23 of the chuck pin 2 is urged radially inwardly of the spinning base 1, that is, in a closing direction. When the ball nut 827 of the ball screw mechanism 825 is sufficiently lowered, the substrate W is held by the chuck pin 2 because of the spring force of the helical compression spring 847. Thus, the resilience of the helical compression spring 847 is used to resiliently hold the substrate W. This is advantageous in causing less damage to the substrate W.

Sensor parts 848 for detecting the height of the cooperating ring 812 are provided to detect a state in which the substrate W is held by the chuck pin 2, as shown in FIG. 7. Each of the sensor parts 848 has, for example, three sensors disposed so as to detect the cooperating ring 812 at three heights: a first height corresponding to a state in which the substrate gripping part 23 of the chuck pin 2 is retracted from the edge of the substrate W; a second height corresponding to a state in which the chuck pin 2 abuts against the edge of the substrate W to grip the substrate W; and a third height corresponding to a state in which the substrate W is absent on the spinning base 1 and the substrate gripping part 23 of the chuck pin 2 is positioned radially inwardly of the spinning base 1 from the position of the edge of the substrate W. Of the three heights, the first height is the highest, the second height is the next highest, and the third height is the lowest. The holding state of the substrate W by the chuck pin 2, the non-holding state of the substrate W, and the absence of the substrate W are detected based on an output from the sensor parts 848. Another sensor for detecting the height of the non-rotating movable member 830 may be provided to check whether the upward and downward movements of the cooperating ring 812 and the ball nut 827 of the ball screw mechanism 825 are in cooperation with each other or not.

The chuck pin 2 is made of an electrically conductive resin (for example, conductive PEEK (poly(ether ether ketone))), and the parts constituting the motion conversion mechanism are made of an electrically conductive resin or metal (stainless steel (SUS) and the like). The lower plate 814 of the spinning base 1 is also made of an electrically conductive material (for example, SiC or aluminum). The rotary shaft 31 to which the lower plate 814 is coupled is made of metal such as SUS, and the casing (made of metal) of the motor M is grounded. This forms a grounding path from the chuck pin 2 through the motion conversion mechanism, the lower plate 814 and the rotary shaft 31 to the casing of the motor M, to discharge static electricity resulting from friction between the substrate W and a processing liquid (the liquid chemical and pure water) supplied to the surface of the substrate W, thereby preventing electrostatic discharge damage to a device manufactured in the substrate W. The drive mechanism of the chuck pin 2 may be used to remove electricity from the substrate W during the spinning process. This eliminates the need to additionally provide a discharge type or X-ray type static eliminator, thereby facilitating design and achieving cost reduction. The discharge type static eliminator presents the problem of the generation of metal particles, and the X-ray type static eliminator presents the problem of radiologic countermeasures. The construction according to the first preferred embodiment does not present such problems.

<2. Processing Operation>

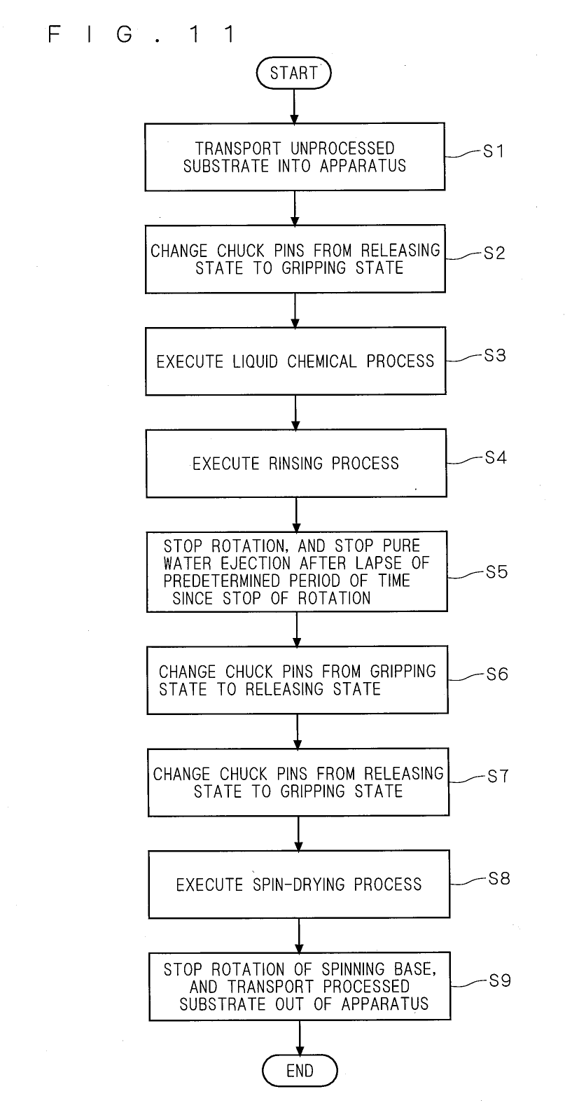

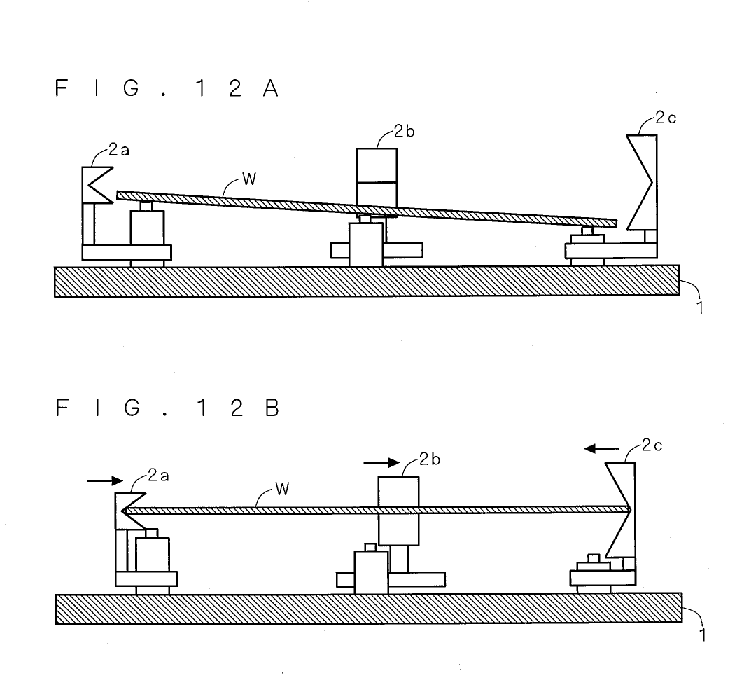

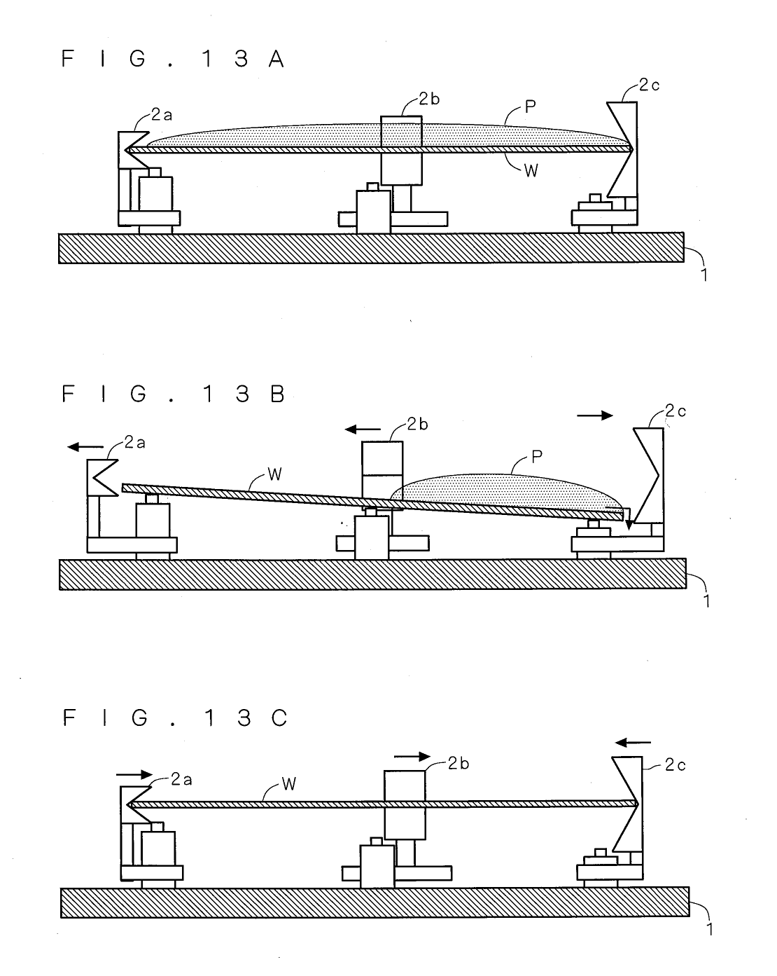

A procedure for the execution of the processes on the substrate W in the substrate processing apparatus 100 will be described with reference to FIGS. 11, 12A, 12B, 13A, 13B and 13C. FIG. 11 is a flow diagram showing the procedure of the execution of the processes on the substrate W in the substrate processing apparatus 100. FIGS. 12A, 12B, 13A, 13B and 13C are sectional views of the spinning base 1 in respective steps during the execution of the processes. A basic procedure in the substrate processing apparatus 100 includes performing a process (e.g., an etching process) using a liquid chemical on a substrate W, performing a rinsing process for rinsing out the liquid chemical from the substrate W with pure water, and then performing a spin-drying process for rotating the substrate W at a high speed to spin off droplets of water from the substrate W.

More specifically, the procedure is classified into two types: a first type including performing the rinsing process and the spin-drying process on bare silicon (having an oxide film formed on the surface thereof) after a hydrofluoric acid process (a process employing hydrofluoric acid (HF) as the liquid chemical); a second type including performing the rinsing process and the spin-drying process on polysilicon (poly-Si) subjected to the hydrofluoric acid process. In either case, the surface of the substrate W subjected to the liquid chemical process is hydrophobic.

First, the controller 99 controls the elevating mechanism 42 to move the barrier plate 4 a large distance upwardly to bring the barrier plate 4 in widely spaced apart relation to the spinning base 1, and also controls the chuck pin drive mechanism 21 to place the plurality of chuck pins 2 in the releasing state. In this state, a transport robot (not shown) transfers an unprocessed substrate W to the spinning base 1. The substrate W transferred to the spinning base 1 is supported in an inclined position by the support pins 22 (in Step S1), as shown in FIG. 12A.

Next, the controller 99 controls the chuck pin drive mechanism 21 to operate the plurality of chuck pins 2 in cooperation with each other, thereby changing the plurality of chuck pins 2 from the releasing state to the gripping state (in Step S2), as shown in FIG. 12B. Then, the unprocessed substrate W supported in the inclined position by the support pins 22 is gripped in a horizontal position by the substrate gripping parts 23.

Next, the liquid chemical process is executed (in Step S3). Specifically, the controller 99 controls the rotatable drive mechanism 3 to rotate the substrate W held by the chuck pins 2 together with the spinning base 1. In this step, the controller 99 controls the elevating mechanism 42 to move the barrier plate 4 downwardly to a position in close proximity to the substrate W, and also controls the rotatable drive mechanism 41 to rotate the barrier plate 4 at the same rpm as the substrate W. In this state, the controller 99 opens the liquid chemical valves 63 and 53 to cause the upper surface nozzle 62 and the lower surface nozzle 52 to eject the liquid chemical therefrom onto the upper and lower surfaces of the substrate W. The ejected liquid chemical spreads over the entire upper surface of the substrate W by centrifugal force, and the liquid chemical process on the upper surface of the substrate W proceeds. After the liquid chemical process for a predetermined period of time is completed, the controller 99 closes the liquid chemical valves 63 and 53 to stop the ejection of the liquid chemical from the upper surface nozzle 62 and the lower surface nozzle 52.

Next, the rinsing process is executed (in Step S4). Specifically, the controller 99 opens the pure water valves 65 and 55 to cause the upper surface nozzle 62 and the lower surface nozzle 52 to eject pure water therefrom onto the upper and lower surfaces of the substrate W while rotating the substrate W. The ejected pure water spreads over the entire upper and lower surfaces of the substrate W by centrifugal force caused by the rotation, and the rinsing process for rinsing out the liquid chemical from the substrate W with pure Water proceeds.

After a lapse of a predetermined period of time since the start of the rinsing process, the controller 99 controls the rotatable drive mechanism 3 to gradually decrease the speed of rotation of the spinning base 1 to finally stop the rotation thereof. After a lapse of a predetermined period of time (e.g., approximately five seconds) since the stop of the rotation, the controller 99 closes the pure water valves 65 and 56 to stop the ejection of pure water from the upper surface nozzle 62 and the lower surface nozzle 52 (in Step S5). When the spinning base 1 is rotating at an extremely low speed, a liquid mass P of pure water starts growing on the upper surface of the substrate W (in a liquid mass growing step). The liquid mass P covering the substrate W grows more (in a liquid film covering step), as shown in FIG. 13A, by the continuous supply of pure water after the stop of the rotation of the spinning base 1.

Next, the controller 99 controls the chuck pin drive mechanism 21 to operate the plurality of chuck pins 2 in cooperation with each other, thereby changing the plurality of chuck pins 2 from the gripping state to the releasing state (in Step S6). Then, the substrate W having been gripped in a horizontal position by the substrate gripping parts 23 is supported in an inclined position by the support pins 22. When the substrate W is placed in the inclined position, the liquid mass P covering the substrate W is moved downwardly along the inclined axis Lo by gravity while being held in the form of a single liquid mass P without breaking up into smaller masses, and is finally removed from the upper surface of the substrate W (as shown in FIG. 13B).

After a predetermined period of time has elapsed since the substrate W was supported in the inclined position so that the entire surface of the substrate W becomes an exposed region (from which the liquid mass P is removed) (that is, after the liquid mass P falls from the upper surface of the substrate W), the controller 99 controls the chuck pin drive mechanism 21 to operate the plurality of chuck pins 2 in cooperation with each other, thereby changing the plurality of chuck pins 2 from the releasing state to the gripping state (in Step S7). Then, the substrate W having been supported in the inclined position by the support pins 22 is gripped in a horizontal position by the substrate gripping parts 23 (as shown in FIG. 13C). When the angle θ of inclination equals 0.3 degree, a time interval during which the substrate W is supported in the inclined position (i.e., a time interval between the instant at which the plurality of chuck pins 2 are placed in the releasing state and the instant at which the plurality of chuck pins 2 are change from the releasing state to the gripping state) is, for example, approximately five seconds.

Next, the spin-drying process is executed (in Step S8). Specifically, the controller 99 controls the rotatable drive mechanism 3 to rotate the substrate W held by the chuck pins 2 together with the spinning base 1. In this step, the controller 99 controls the elevating mechanism 42 to move the barrier plate 4 downwardly to a position in close proximity to the substrate W, and also controls the rotatable drive mechanism 41 to rotate the barrier plate 4 at the same rpm as the substrate W. Droplets of water deposited on the substrate W are spun off by centrifugal force caused by the rotation, whereby the spin-drying process proceeds.

After a lapse of a predetermined period of time since the start of the spin-drying process, the controller 99 controls the rotatable drive mechanism 3 to stop the rotation of the spinning base 1 and the substrate W held by the spinning base 1. The controller 99 also controls the rotatable drive mechanism 41 to stop the rotation of the barrier plate 4, and controls the elevating mechanism 42 to move the barrier plate 4 upwardly, thereby bringing the barrier plate 4 in spaced apart relation to the spinning base 1. Further, the controller 99 controls the chuck pin drive mechanism 21 to operate the plurality of chuck pins 2 in cooperation with each other, thereby changing the plurality of chuck pins 2 from the gripping state to the releasing state. Then, the substrate W having been gripped in the horizontal position by the substrate gripping parts 23 is transferred to the spinning base 1 and supported in an inclined position by the support pins 22. In this state, the transport robot not shown takes the processed substrate W from the spinning base 1 to transport the processed substrate W outwardly (in Step S9). This completes a series of processes of the substrate W.

<3. Effects>

According to first preferred embodiment, the support pins 22 support the substrate W, when the chuck pins 2 are in the releasing state, to place the substrate W in an inclined position. This enables the processing liquid to be drained from the surface of the substrate W by gravity. The substrate W with the processing liquid drained from the surface thereof is held and rotated in a horizontal position. This prevents the occurrence of water marks to achieve good drying of the surface of the substrate W.

The first preferred embodiment, which uses gravity to drain the processing liquid from the surface of the substrate W, eliminates the need to spray a gas onto the substrate W to blow the processing liquid off the surface of the substrate W. This also produces the effect of avoiding the occurrence of water marks resulting from the spraying of the gas onto the surface of the substrate W.

According to the first preferred embodiment, the movable body members 24 are rotated to move the substrate gripping parts 23 from the gripping position to the releasing position. In other words, only releasing the grip of the substrate W achieves the change from the state in which the substrate W is held in a horizontal position to the state in which the substrate W is supported in an inclined position. This eliminates the need to provide a special mechanism such as an arm for raising a single edge portion of the substrate W and the like to place the substrate W in an inclined position, and achieves the inclination of the substrate W using a simple structure without giving rise to the increase in costs of the apparatus and in footprint. Additionally, there is no need to provide the step of controlling such a mechanism to raise a single edge portion of the substrate W, thereby avoiding the decrease in throughput.

According to the first preferred embodiment, the support pins 22 which function as the substrate rest part for supporting the substrate W in an inclined position are rinsed and dried at the same time that the substrate W is rinsed and dried. Accumulated contamination is therefore avoided without the provision of a special mechanism for rinsing the support pins 22 and the like. This prevents the contamination of the substrate W if the support pins 22 come in contact with the lower surface of the substrate W.

### Second Preferred Embodiment

<1. Construction>

The construction of a substrate processing apparatus 200 according to a second preferred embodiment of the present invention will be described. The substrate processing apparatus 200 according to the second preferred embodiment of the present invention includes chuck pins 20a, 20b and 20c (referred to simply as “chuck pins 20,” unless otherwise identified) in place of the chuck pins 2a, 2b and 2c of the first preferred embodiment. Differences from the first preferred embodiment will be described below, whereas other than the differences will not be described. Like reference numerals and characters are used to designate components identical with those of the first preferred embodiment.

<1-1. Chuck Pins 20>

Like the chuck pins 2 according to the first preferred embodiment, the plurality of chuck pins 20 according to the second preferred embodiment are provided in predetermined locations on the upper surface of a spinning base 201 (see FIG. 2). The arrangement and position of the chuck pins 20a, 20b and 20c are similar to the arrangement and position of the chuck pins 2a, 2b and 2c. The plurality of chuck pins 20 (more specifically, upper surfaces 241 of movable body members 240 of the respective chuck pins 20) collectively function as a substrate rest part for placing a substrate W in an inclined position thereon. Additionally, the plurality of chuck pins 20 (more specifically, substrate gripping parts 230 provided in the respective chuck pins 20) collectively function as a gripping part for gripping an edge portion of the substrate W placed in an inclined position to separate the substrate W from the substrate rest part, thereby holding the substrate W in a horizontal position in spaced apart relation to the substrate rest part. The plurality of chuck pins 20 are pivotably driven in cooperation with each other by the chuck pin drive mechanism 21 to change between the releasing state in which the chuck pins 20 function as the substrate rest part and the gripping state in which the chuck pins 20 function as the gripping part.

<1-2. Construction of Chuck Pins 20a, 20b and 20c>

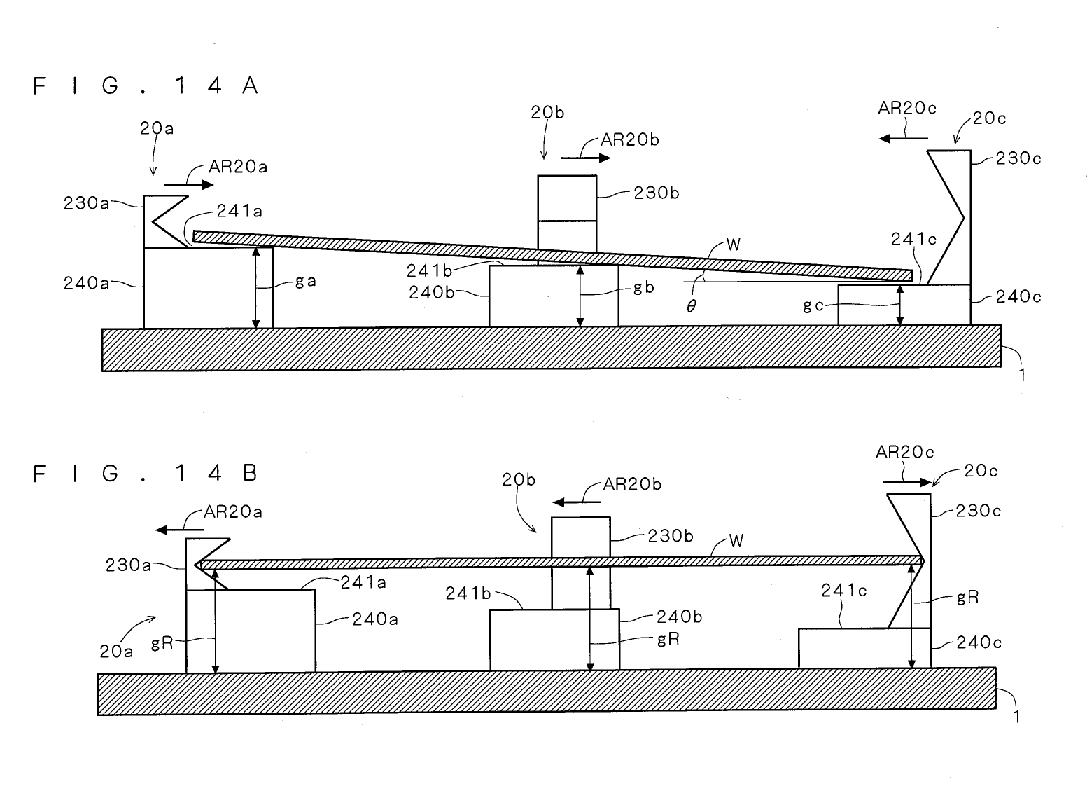

The construction of the chuck pins 20a, 20b and 20c will be described with reference to FIGS. 14A and 14B. FIGS. 14A and 14B are sectional views of the spinning base 201 (taken along the line Lo of FIG. 2).

The chuck pins 20a, 20b and 20c include substrate gripping parts 230a, 230b and 230c, respectively, for pressing the peripheral edge of the substrate W sidewise to grip the peripheral edge of the substrate W. The substrate gripping parts 230a, 230b and 230c are referred to simply as the “substrate gripping parts 230” hereinafter, unless otherwise identified. The substrate gripping parts 230a, 230b and 230c are provided on generally cylindrical movable body members 240a, 240b and 240c, respectively, which are rotatably supported on vertical axes. The movable body members 240a, 240b and 240c are referred to simply as the “movable body members 240” hereinafter, unless otherwise identified.

The movable body members 240a, 240b and 240c have upper surfaces 241a, 241b and 241c, respectively, which support the lower surface of the substrate W. The upper surfaces 241a, 241b and 241c are referred to simply as the “upper surfaces 241” hereinafter, unless otherwise identified.

The upper surface 241a of the movable body member 240a is positioned at a height (referred to hereinafter as a “first height ga”) which is spaced the predetermined distance ga apart from the surface of the spinning base 201 which is a horizontal surface. That is, the upper surface 241a supports the substrate W at the first height ga on the contour axis La.

The upper surface 241b of the movable body member 240b is positioned at a height (referred to hereinafter as a “second height gb”) which is spaced the predetermined distance gb (where the distance gb<the distance ga) apart from the surface of the spinning base 201. That is, the upper surface 241b supports the substrate W at the second height gb on the contour axis Lb.

The upper surface 241c of the movable body member 240c is positioned at a height (referred to hereinafter as a “third height gc”) which is spaced the predetermined distance gc (where the distance gc<the distance gb) apart from the surface of the spinning base 201. That is, the upper surface 241c supports the substrate W at the third height gc on the contour axis Lc.

The substrate gripping parts 230a, 230b and 230c are provided on the movable body members 240a, 240b and 240c at eccentric positions relative to the rotation centers of the movable body members 240a, 240b and 240c, respectively. Thus, the movable body members 240a, 240b and 240c are driven by the chuck pin drive mechanism 21 to rotate, thereby causing the substrate gripping parts 230a, 230b and 230c to move toward and away from the substrate W (as indicated by arrows AR20a, AR20b and AR20c). This enables the substrate gripping parts 230a, 230b and 230c to change between the gripping position (the position shown in FIG. 14B) at which the substrate gripping parts 230a, 230b and 230c form the pressing state and the releasing position (the position shown in FIG. 14A) at which the substrate gripping parts 230a, 230b and 230c form the releasing state. The substrate gripping parts 230a, 230b and 230c are similar in specific construction to the substrate gripping parts 23a, 23b and 23c. The innermost edges K of the V-shaped cross-sectional recesses of the substrate gripping parts 230a, 230b and 230c are positioned at a height which is spaced a predetermined distance gR (where the distance gR>the distance ga) apart from the surface of the spinning base 201. That is, the substrate gripping parts 230a, 230b and 230c fix and hold the substrate W at the height gR at their gripping position.

As discussed above, when the substrate gripping parts 230a, 230b and 230c are at the releasing position, the substrate gripping parts 230a, 230b and 230c are spaced apart from the edge of the substrate W, and the upper surfaces 241a, 241b and 241c of the movable body members 240a, 240b and 240c at the heights differing from each other support the substrate W to thereby support the substrate W in an inclined position (as shown in FIG. 14A). In other words, the chuck pins 20a, 20b and 20c collectively function as the substrate rest part for placing the substrate W in an inclined position in this case.

When the substrate gripping parts 230a, 230b and 230c are at the gripping position, the tapered surfaces of the substrate gripping parts 230a, 230b and 230c press the edge of the substrate W, grip the substrate W placed on the upper surfaces 241a, 241b and 241c of the movable body members 240a, 240b and 240c sidewise therebetween to raise and separate the substrate W from the surface rest part, and grip and hold the substrate W in a horizontal position at the height gR (as shown in FIG. 14B). In other words, the chuck pins 20a, 20b and 20c function as the gripping part for holding the substrate W in a horizontal position in this case.

<2. Processing Operation>

A basic procedure for the execution of the processes in the substrate processing apparatus 200 according to the second preferred embodiment is similar to that in the substrate processing apparatus 100 according to the first preferred embodiment. The difference lies in that, although the substrate W is supported in an inclined position by the support pins 22 when the chuck pins 2 are placed in the releasing state according to the first preferred embodiment, the substrate W is supported in an inclined position by the upper surfaces 241 of the movable body members 240, rather than the support pins 22, according to the second preferred embodiment.

[Modifications]

<First Modification>

For the execution of the drying process in the above-mentioned preferred embodiments, nitrogen gas may be supplied to the surface of the substrate W so that the drying process is performed in a nitrogen atmosphere.

Specifically, after the rinsing process for a predetermined period of time is completed (in Step S4), the controller 99 may open the gas valve 72 to cause the ejection of the nitrogen gas from the gas supply passage 71 while the barrier plate 4 is maintained in close proximity to the substrate W. The ejected nitrogen gas flows between the barrier plate 4 and the substrate W to create a low oxygen concentration atmosphere around the substrate W. The occurrence of water marks is prevented by executing the spin-drying process in Step S8 in the low oxygen concentration atmosphere to which the nitrogen gas is supplied.

It is desirable that the supply of the nitrogen gas is timed to start after at least the center of the substrate W becomes the exposed region (i.e., after a liquid mass P on the surface of the substrate W passes through the center of the substrate W). This is because there is apprehension about the occurrence of water marks if a gas is ejected onto the substrate W the center of which is covered with the processing liquid. Starting the ejection of the gas onto the substrate W after the processing liquid is removed from the surface of the substrate placed in an inclined position so that at least the center of the substrate becomes the exposed region prevents the occurrence of such water marks to achieve good drying of the substrate W. Additionally, the substrate W is dried rapidly because a flow of gas does not hinder the drainage of the liquid.

Alternatively, the start of the supply of the nitrogen gas may be timed to coincide with the completion of the process in Step S5. In this case, the flow rate of the supplied gas is decreased to such an extent as not to hinder the drainage of the liquid while the processes in Steps S6 and S7 are executed (or while the substrate W is supported in an inclined position).

<Second Modification>

In the first preferred embodiment, the plurality of chuck pins 2 are changed from the releasing state to the gripping state (in Step S7) after a predetermined period of time has elapsed since the substrate W was supported in the inclined position so that the liquid mass P falls from the upper surface of the substrate W. The change from the releasing state to the gripping state may be timed to be made after at least the center of the substrate W becomes the exposed region in Step S6. That is, after the center of the substrate W becomes the exposed region, the controller 99 may control the chuck pin drive mechanism 21 to operate the plurality of chuck pins 2 in cooperation with each other, thereby changing the plurality of chuck pins 2 from the releasing state to the gripping state.

Making a transition to the process in Step S7 by holding the substrate W in the horizontal position after at least the center of the substrate W becomes the exposed portion achieves good drying of the substrate W while improving throughput. According to this processing step, the substrate W is supported in an inclined position, for example, for approximately three seconds. Thus, the processing time is shortened.

<Third Modification>

In the first preferred embodiment, the same processing part in the substrate processing apparatus 100 is adapted to perform a series of processes (the liquid chemical process, the rinsing process and the spin-drying process) sequentially on a substrate W. Alternatively, the substrate processing apparatus may be configured so that a first processing part performs a series of processes in Steps S1 to S5 mentioned above on a substrate W, and the substrate W subjected to the processes in Steps S1 to S5 is transported into a second processing part. In this case, the first processing part performs processes corresponding to Steps S1 to S5 mentioned above, and the substrate W having the surface covered with the liquid mass P is transported in a horizontal position by the transport robot into the aforementioned processing part (the second processing part) of the substrate processing apparatus 100. The substrate W transported into the second processing part is transferred to the spinning base 1. The substrate W transferred to the spinning base 1 is supported in an inclined position by the support pins 22. In this case, the controller 99 executes processes in Step S6 and its subsequent steps mentioned above on the substrate W.

<Other Modifications>

In the first preferred embodiment, the support pins 22 are mounted to the movable body members 24 of the chuck pins 2. Alternatively, the support pins 22 may be mounted directly to the spinning base 1.

While the invention has been described in detail, the foregoing description is in all aspects illustrative and not restrictive. It is understood that numerous other modifications and variations can be devised without departing from the scope of the invention.

What is claimed is:

1. A substrate processing apparatus for removing a processing liquid from a surface of a substrate to dry said substrate, comprising:
a rotatable support table for rotatably supporting a substrate;
a substrate rest part provided on said rotatable support table and for placing a substrate in an inclined position thereon;
a gripping part provided on said rotatable support table and for gripping an edge portion of a substrate to hold the substrate in a horizontal position;
a drive mechanism for moving said gripping part so that said gripping part is changed between a horizontal holding state in which said gripping part grips the edge portion of the substrate to hold the substrate in the horizontal position and an inclined holding state in which said gripping part is spaced apart from the edge portion of the substrate and said substrate rest part holds the substrate in the inclined position; and
a rotating element for rotating said rotatable support table about a vertical axis in said horizontal holding state.

2. The substrate processing apparatus according to claim 1, wherein:
said substrate rest part includes a plurality of support pins differing in height from each other;
said gripping part includes a plurality of grippers provided in a one-to-one correspondence with said plurality of support pins;
said plurality of support pins and said plurality of grippers corresponding thereto are provided on a plurality of rotatable bases, respectively, which are mounted on said rotatable support table rotatably on a vertical axis;
each of said plurality of grippers has tapered surfaces of a V-shaped cross-sectional configuration which receive the edge portion of the substrate;
said plurality of grippers are provided on said plurality of rotatable bases at eccentric positions relative to the rotation centers of said plurality of rotatable bases, respectively; and
by rotating said plurality of rotatable bases, said drive mechanism brings said plurality of grippers in spaced apart relation to the edge portion of the substrate to place the substrate on said plurality of support pins, and also presses the tapered surfaces of said plurality of grippers against the edge portion of the substrate to bring the substrate in spaced apart relation to said plurality of support pins, thereby causing said plurality of grippers to grip the substrate.

3. The substrate processing apparatus according to claim 2, further comprising
a processing liquid supply part for supplying a processing liquid to the surface of the substrate held in the horizontal position by said gripping part.

4. The substrate processing apparatus according to claim 3, further comprising
a gas supply part for supplying a gas to the surface of the substrate.

5. A substrate processing apparatus for removing a processing liquid from a surface of a substrate to dry said substrate, comprising:
a substrate rest part for placing a substrate in an inclined position thereon;
a gripping part for bringing the substrate placed on the substrate rest part into spaced apart relation to said substrate rest part to hold the substrate in a horizontal position; and
a substrate rotating mechanism for rotating the substrate held in the horizontal position by said gripping part.

6. The substrate processing apparatus according to claim 5, further comprising
a processing liquid supply part for supplying a processing liquid to the surface of the substrate held in the horizontal position by said gripping part.

7. The substrate processing apparatus according to claim 6, further comprising
a gas supply part for supplying a gas to the surface of the substrate.

8. A method of removing a processing liquid from a surface of a substrate to dry said substrate, comprising the steps of:
a) placing a substrate with a processing liquid remaining on a surface thereof in an inclined position thereon;
b) changing the position of the substrate placed in the inclined position to hold the substrate in a horizontal position; and
c) rotating the substrate held in a horizontal position after changing the position of the substrate.

9. The method according to claim 8, further comprising the step of
d) supplying said processing liquid to the surface of the substrate held in the horizontal position,
said step d) being executed before said step a).

10. The method according to claim 9, further comprising the step of
e) transporting the substrate to which said processing liquid is supplied in a horizontal position from a first processing part to a second processing part,
said step e) being executed after said step d),
said step d) being executed in said first processing part,
said step a) being executed in said second processing part.

11. The method according to claim 10, wherein
said step b) is executed after said processing liquid is removed from the surface of the substrate placed in the inclined position in said step a) so that at least the center of the substrate becomes an exposed region from which said processing liquid is removed.

12. The method according to claim 11, further comprising the step of
f) supplying a gas to the surface of the substrate,
said step f) being started after said processing liquid is removed from the surface of the substrate placed in the inclined position in said step a) so that at least the center of the substrate becomes the exposed region from which said processing liquid is removed.
